(19) United States
(12) Patent Application Publication
(10) Pub. No.: US 2026/0206430 A1
(43) Pub. Date: Jul. 16, 2026

(54) DISPLAY PANEL, METHOD FOR MANUFACTURING THE SAME, AND DISPLAY DEVICE

(71) Applicants: Xu ZHAO, Wuhan (CN); Qiyong KE, Wuhan (CN); Xiaojin ZHOU, Wuhan (CN)

(72) Inventors: Xu ZHAO, Wuhan (CN); Qiyong KE, Wuhan (CN); Xiaojin ZHOU, Wuhan (CN)

(21) Appl. No.: 19/430,810

(22) Filed: Dec. 23, 2025

(51) Int. Cl. H10K 59/126; H10K 59/12; H10K 59/121; H10K 59/124

(52) U.S. Cl. CPC H10K 59/126; H10K 59/1201; H10K 59/1213; H10K 59/124

(57) ABSTRACT

A display panel, a method for manufacturing the display panel, and a display device. The display panel includes a display area and a substrate. The display area includes a first area and a second area. The second area has a transmittance greater than the first area. The substrate includes a first underlay, a first blocking layer, a second underlay and a first mark. The second underlay is located on a side of the first blocking layer away from the first underlay. The first mark is located between the first underlay and the second underlay. The substrate further includes a first hole. The first hole is located in the second area and penetrates the first underlay and the first blocking layer.

### CROSS-REFERENCE TO RELATED APPLICATION

The present application claims priority to Chinese Patent Application No. 202511350087.X, filed on Sep. 19, 2025, the content of which is incorporated herein by reference in its entirety.

### TECHNICAL FIELD

The present disclosure relates to a field of display technologies and, in particular, to a display panel, a method for manufacturing a display panel, and a display device.

### BACKGROUND

Camera under panel (CUP) is a technology for integrating a camera module under a display panel. By using this technology, a display device can achieve a high screen-to-body ratio, which optimize a full-screen design thereof.

In a display panel applying this technology, in order to improve a transmittance in a CUP area, a hole is usually formed at a position corresponding to the CUP area in a substrate. After the hole is formed, the substrate is uneven in the CUP area, which can easily cause some display defects together with other subsequent film layer structures due to problems, such as alignment issues.

### SUMMARY

An aspect of the present disclosure provides a display panel. The display panel includes a display area and a substrate. The display area includes a first area and a second area. A transmittance of the second area is greater than a transmittance of the first area. The substrate includes a first underlay, a first blocking layer, a second underlay, a first hole and a first mark. The second underlay is located on a side of the first blocking layer away from the first underlay. The first mark is located between the first underlay and the second underlay. The first hole is located in the second area and penetrates the first underlay and the first blocking layer.

Another aspect of the present disclosure provides a method for manufacturing a display panel. The method includes: forming a display motherboard that includes a substrate, the display motherboard includes a plurality of panel areas, one of the plurality of panel areas corresponds to one display panel, one of the plurality of panel areas includes a display area, the display area includes a first area and a second area, a transmittance of the second area is greater than a transmittance of the first area; cutting the display motherboard to form the display panel. A manufacturing process of the substrate includes: forming a first underlay, and forming a first blocking layer and a first mark on a side of the first underlay; forming a first hole, the first hole is located in the second area and penetrates the first underlay and the first blocking layer; and forming a second underlay.

Another aspect of the present disclosure provides a display device. The display device includes a display panel. The display panel includes a display area and a substrate. The display area includes a first area and a second area. A transmittance of the second area is greater than a transmittance of the first area. The substrate includes a first underlay, a first blocking layer, a second underlay, a first hole and a first mark. The second underlay is located on a side of the first blocking layer away from the first underlay. The first mark is located between the first underlay and the second underlay. The first hole is located in the second area and penetrates the first underlay and the first blocking layer.

### BRIEF DESCRIPTION OF DRAWINGS

In order to more clearly explain the embodiments of the present disclosure or the technical solution in the related art, the drawings to be used in the description of the embodiments or the related art will be briefly described below. The drawings in the following description are some embodiments of the present disclosure. For those skilled in the art, other drawings may also be obtained based on these drawings.

FIG. 1 is a schematic diagram of a display panel according to an embodiment of the present disclosure;

FIG. 2 is a schematic diagram of a substrate according to an embodiment of the present disclosure;

FIG. 3 is schematic diagram of a substrate according to another embodiment of the present disclosure;

FIG. 4 is a structural schematic diagram of a display panel according to another embodiment of the present disclosure;

FIG. 5 is a structural schematic diagram of a substrate according to another embodiment of the present disclosure;

FIG. 6 is a schematic diagram of a display panel according to another embodiment of the present disclosure;

FIG. 7 is a schematic diagram of a display panel according to another embodiment of the present disclosure;

FIG. 8 is a schematic diagram where the relative position among the first hole, the second hole, and the filling layer has an offset according to an embodiment of the present disclosure;

FIG. 9 is a top view of a first hole and a filling layer according to an embodiment of the present disclosure;

FIG. 10 is a structural schematic diagram of a display panel according to another embodiment of the present disclosure;

FIG. 11 is a structural schematic diagram of a substrate according to another embodiment of the present disclosure;

FIG. 12 is a schematic diagram of a display panel according to another embodiment of the present disclosure;

FIG. 13 is a schematic diagram of a display panel according to another embodiment of the present disclosure;

FIG. 14 is a schematic diagram of a display panel according to another embodiment of the present disclosure;

FIG. 15 is a schematic diagram of a method for manufacturing a display panel according to an embodiment of the present disclosure;

FIG. 16 is a schematic diagram of a method for manufacturing a display panel according to another embodiment of the present disclosure;

FIG. 17 is a schematic diagram of a method for manufacturing a display panel according to another embodiment of the present disclosure;

FIG. 18 is a schematic diagram of a position of a first mark according to an embodiment of the present disclosure;

FIG. 19 is a schematic diagram of a position of a first mark according to another embodiment of the present disclosure;

FIG. 20 is a schematic diagram of a coverage area of a second underlay according to an embodiment of the present disclosure;

FIG. 21 is a schematic diagram of a method for manufacturing a display panel according to another embodiment of the present disclosure;

FIG. 22 is a schematic diagram of a method for manufacturing a display panel according to another embodiment of the present disclosure;

FIG. 23 is a schematic diagram of a method for manufacturing a display panel according to another embodiment of the present disclosure;

FIG. 24 is a schematic diagram of a method for manufacturing a display panel according to another embodiment of the present disclosure; and

FIG. 25 is a structural schematic diagram of a display device according to an embodiment of the present disclosure.

### DESCRIPTION OF EMBODIMENTS

To better understand the technical solutions of the present disclosure, the following describes the embodiments of the present disclosure in detail with reference to the accompanying drawings. It should be clear that the described embodiments are only a part of the embodiments of the present disclosure, not all embodiments. Based on the embodiments of the present disclosure, all other embodiments obtained by those of ordinary skill in the art shall fall within the protection scope of the present disclosure. The terms used in the embodiments of the present disclosure are only for the purpose of describing specific embodiments, and are not intended to limit the present disclosure.

The terms used in the embodiments of the present disclosure are merely for the purpose of describing specific embodiment, rather than limiting the present disclosure. The terms “a”, “an”, “the” and “said” in a singular form in the embodiment of the present disclosure and the attached claims are also intended to include plural forms thereof, unless noted otherwise.

It should be understood that the term “and/or” used in the context of the present disclosure is to describe a correlation relation of related objects, indicating that there may be three relations, e.g., A and/or B may indicate only A, both A and B, and only B. In addition, the symbol “/” in the context generally indicates that the relation between the objects in front and at the back of “/” is an “or” relationship.

In the related art, when drilling hole in the substrate, only a simple mechanical alignment is performed for a machine for exposure and development. This will result in low precision of the hole drilling position not high, resulting in an offset of the relative position of the drilled holes and other subsequent film layer structures. Because the substrate is uneven at the hole drilling position, when the hole drilling is offset from other subsequent film layer structures, the uneven position is misaligned with other subsequent film layer structures, thereby triggering some display defects.

For example, subsequent other film layer structures include a filling layer, and the filling layer is filled in the hole of the CUP area. If the formed hole in the substrate offsets from the filling layer at a relative position, the filling layer generates a V-shaped large step at one side of a hole wall, and when the upper trace crosses the V-shaped large step, a risk of short circuit and open circuit easily occurs, thereby affecting display.

The present disclosure provides a display panel. The display panel may be an organic light emitting diode (OLED) display panel.

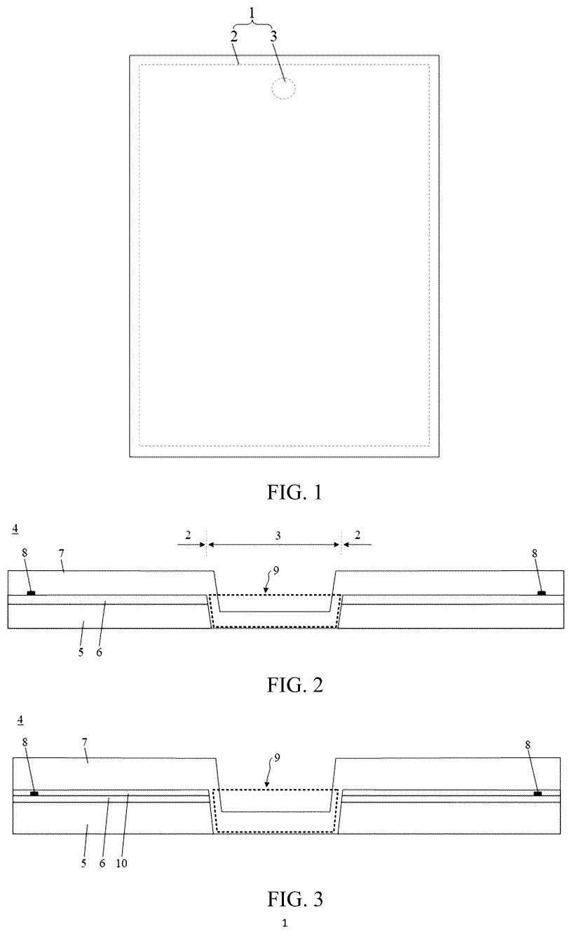

FIG. 1 is a schematic diagram of a display panel according to an embodiment of the present disclosure. As shown in FIG. 1, the display panel includes a display area 1. The display area 1 includes a first area 2 and a second area 3. The first area 2 may be a conventional display area, the second area 3 may be a CUP area corresponding to a camera module, and a transmittance of the second area 3 is greater than a transmittance of the first area 2.

FIG. 2 is a schematic diagram of a substrate according to an embodiment of the present disclosure. As shown in FIG. 2, the display panel further includes a substrate 4. The substrate 4 includes a first underlay 5, a first blocking layer 6, a second underlay 7, and a first mark 8. The first underlay 5 and the second underlay 7 may be flexible underlays such as polyimide (PI). The second underlay 7 is located on a side of the first blocking layer 6 away from the first underlay 5, and the first mark 8 is located between the first underlay 5 and the second underlay 7. The substrate 4 further includes a first hole 9. The first hole 9 is located in the second area 3 and penetrates the first underlay 5 and the first blocking layer 6.

According to an embodiment of the present disclosure, the first mark 8 is additionally arranged in the substrate 4, and the first mark 8 may be used as an auxiliary structure for improving a hole drilling precision of the first hole 9. In the hole drilling process, the first mark 8 is identified, the hole drilling position can be positioned and limited by using the first mark 8, so that the hole drilling position is accurately controlled, and the relative position offset between the first hole 9 and other subsequent film layer structures is avoided.

Moreover, the first mark 8 may also be used to establish an indirect alignment relationship between the first hole 9 and other subsequent film layer structures. For example, in the manufacturing process, other subsequent film layer structures may directly use the first mark 8 as an alignment reference, so that an indirect alignment relationship is established between these film layer structures and the first hole 9, and the accurate alignment between these structures is achieved. In an embodiment of the present disclosure, an alignment mark A is included above the substrate 4, and the alignment mark A takes the first mark 8 as an alignment reference during the forming process to form an indirect alignment relationship between the alignment mark A and the first hole 9. Further, when some other subsequent film layer structures are formed with the alignment mark A as an alignment reference, an indirect alignment relationship may also be established between these film layer structures and the first hole to achieve accurate alignment between these structures. Further, the alignment relationship may also be transmitted upward step by step, for example, an alignment mark B may be further formed by using the alignment mark A as an alignment reference subsequently, and then an indirect alignment relationship is also formed between the alignment mark B and the first hole 9, so that when some other subsequent film layer structures use the alignment mark B as an alignment reference in the forming process, the indirect alignment relationship is also established between these film layer structures and the first hole, so that the relative position offset between these film layers or formed holes and the first hole is avoided.

In summary, the present disclosure can avoid the relative position offset between the formed hole in the substrate 4 and other subsequent film layer structures, further, some display defects caused by the position offset are avoided. For example, according to the technical solutions, the position offset between the formed hole in the substrate 4 and the filling layer filled in the hole may be avoided, the filling layer may better fill the hole, a V-shaped large step will not be generated on one side, so that short circuit or open circuit may be avoided when the upper trace crosses the V-shaped large step.

In an embodiment of the present disclosure, referring again to FIG. 2, the first mark 8 is located between the first blocking layer 6 and the second underlay 7.

The first mark 8 is formed above the first blocking layer 6, which can enhance the adhesion of the first mark 8, and the first mark 8 has high stability, thereby playing a reliable role in the hole drilling of the first hole 9 and the subsequent transmission of alignment relationship.

FIG. 3 is schematic diagram of a substrate according to another embodiment of the present disclosure. In an embodiment of the present disclosure, as shown in FIG. 3, the substrate 4 further includes a second blocking layer 10. The second blocking layer 10 is located between the first blocking layer 6 and the second underlay 7, and the first mark 8 is located between the first blocking layer 6 and the second blocking layer 10.

The blocking layer is mainly used to improve adhesion of the underlay. When the first mark 8 is formed above the first blocking layer 6, the manufacturing process of the first mark 8 may affect the first blocking layer 6, thereby affecting the adhesion of the second underlay 7. According to an embodiment of the present disclosure, the second blocking layer 10 is formed above the first mark 8, the second blocking layer 10 is not affected by the manufacturing process of the first mark 8, and the second blocking layer 10 may be firmly bonded to the second underlay 7 above.

For example, generally, the blocking layer includes a SiOx layer and a-Si layer that are stacked, and the adhesion between the blocking layer and the upper underlay is mainly achieved through the a-Si layer. However, the a-Si layer is thin, and its thickness is only about 30 Å. When the first mark 8 is formed above the first blocking layer 6, the formation of the first mark 8 undergoes a series of processes, which will have an influence on the a-Si layer that is already very thin in the first blocking layer 6. By further forming a second blocking layer 10 above the first mark 8, the a-Si layer in the second blocking layer 10 is not affected by the manufacturing process of the first mark 8, and thus may be well adhered to the second underlay 7.

In an embodiment of the present disclosure, referring again to FIG. 3, the first hole 9 further penetrates the second blocking layer 10, that is, after the first mark 8 is formed, the second blocking layer 10 is formed first, and then the first hole 9 is formed.

The second blocking layer 10 is penetrated by the first hole 9, which can further improve the transmittance of the second area 3, which further improves the photographing effect.

In an embodiment of the present disclosure, in an embodiment of the present disclosure, after the first mark 8 is formed, the first hole 9 may be formed first, and then the second blocking layer 10 is formed, at this time, the second blocking layer 10 is not penetrated by the first hole 9.

In an embodiment of the present disclosure, a thickness of the second blocking layer 10 is less than a thickness of the first blocking layer 6, and/or the thickness of the second blocking layer 10 is less than or equal to 2000 Å.

The second blocking layer 10 has a smaller thickness, which may reduce the shielding of the second blocking layer 10 on the first mark 8 and avoid affecting the identification of the first mark 8. For example, in a structure in which the second blocking layer 10 is penetrated by the first hole 9, when the first hole 9 is formed, even if the second blocking layer 10 is covered above the first mark 8, the first mark 8 may still be accurately captured and aligned.

In an embodiment of the present disclosure, the first blocking layer 6 and the second blocking layer 10 may be regarded as being formed by dividing an original blocking layer between the first underlay 5 and the second underlay 7. For example, the thickness of the original blocking layer between the first underlay 5 and the second underlay 7 is 5000 Å, the film layer with the thickness of 5000 Å may be divided into the first blocking layer 6 with a thickness of 3000 Å and the second blocking layer 10 with a thickness of 2000 Å, in this way, the gap between the first underlay 5 and the second underlay 7 remains unchanged.

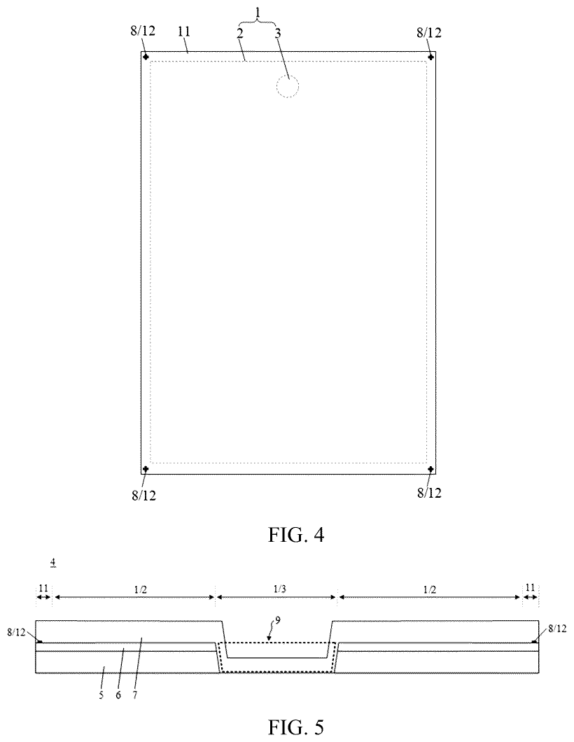

FIG. 4 is a structural schematic diagram of a display panel according to another embodiment of the present disclosure, and FIG. 5 is a structural schematic diagram of a substrate according to another embodiment of the present disclosure. In an embodiment of the present disclosure, as shown in FIG. 4 and FIG. 5, the display panel further includes a non-display area 11, the non-display area 11 at least partially surrounds the display area 1.

The first mark 8 includes a first alignment mark 12, and the first alignment mark 12 is located in the non-display area 11.

The first alignment mark 12 is used for accurately positioning the hole drilling position of the first hole 9 in the manufacturing process of the first hole 9 and establishing an indirect alignment relationship between the first hole 9 and other subsequent film layer structures. According to an embodiment of the present disclosure, the first alignment mark 12 may be located at an edge of the non-display area 11 adjacent to the display panel, for example, at a top corner of the display panel as shown in FIG. 5. Compared with the display area 1, the first alignment mark 12 is arranged in the non-display area 11, and the size, shape, thickness and other parameters of the first alignment mark 12 may be designed more flexibly, so that the first alignment mark 12 has a larger thickness or a larger size, thereby making it easier to be identified.

The shape of the first alignment mark 12 may be various, such as a cross shape or a straight shape, which is not limited in embodiments of the present disclosure.

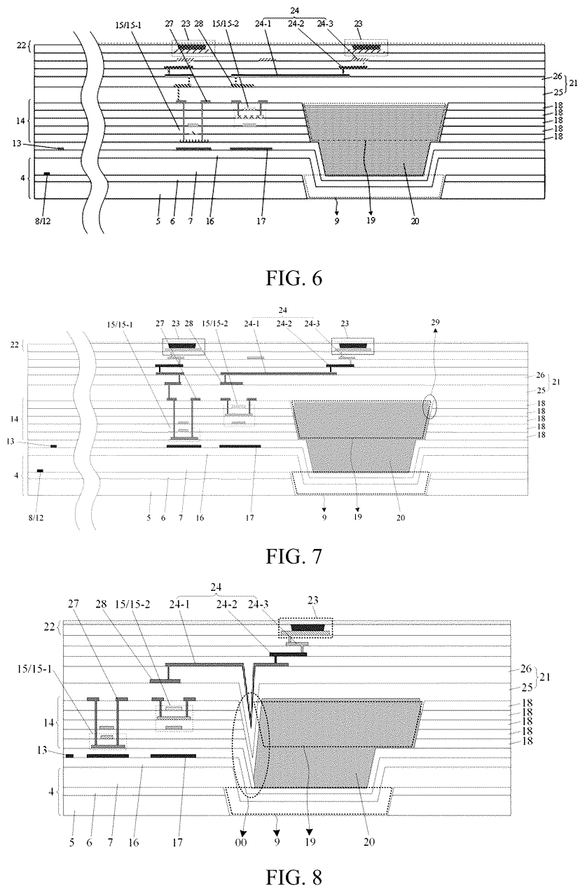

FIG. 6 is a schematic diagram of a display panel according to another embodiment of the present disclosure, and FIG. 7 is a schematic diagram of a display panel according to another embodiment of the present disclosure. In an embodiment of the present disclosure, as shown in FIG. 6 and FIG. 7, the display panel further includes a second alignment mark 13, and the second alignment mark 13 is located on a side of the second underlay 7 away from the first blocking layer 6.

In an embodiment of the present disclosure, the second alignment mark 13 is formed by using the first mark 8 as an alignment reference, for example, the second alignment mark 13 is formed by using the first alignment mark 12 as an alignment reference.

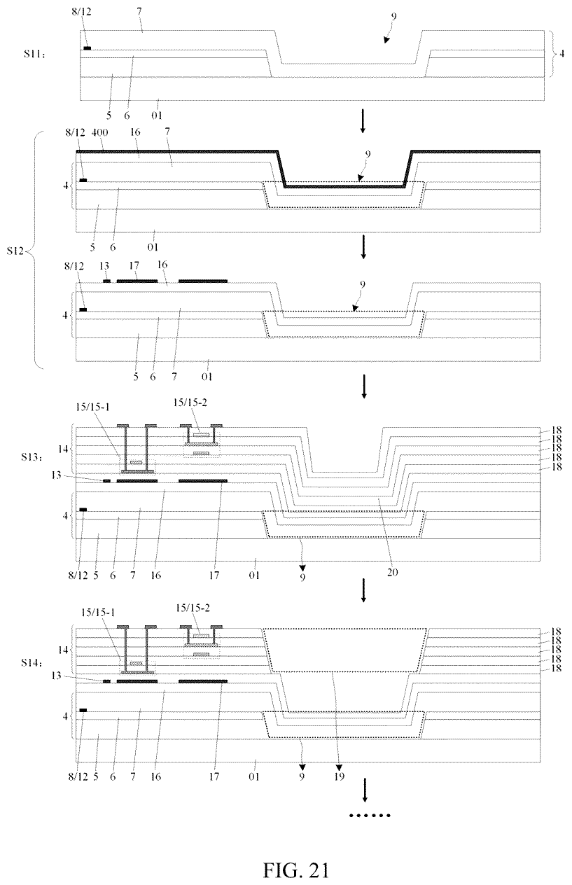

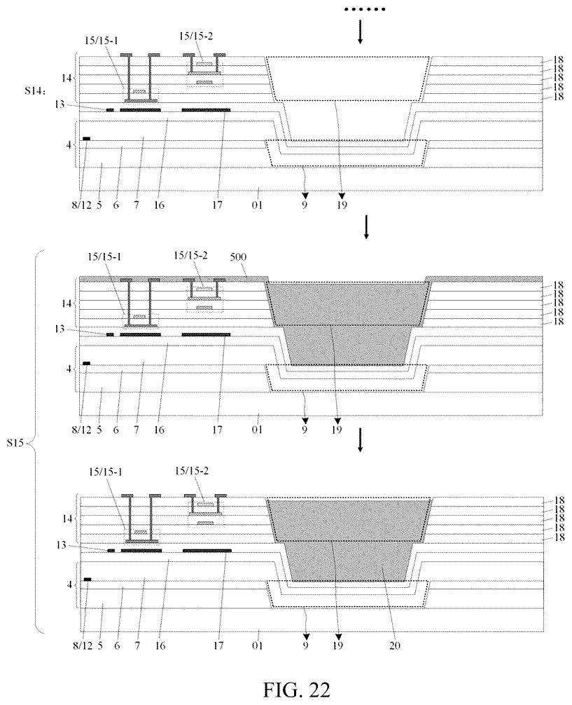

With reference to FIG. 21 and FIG. 22, in the manufacturing process of the second alignment mark 13, a first film layer 400 is first formed, and then the first film layer 400 is patterned to form the second alignment mark 13. In the process of exposing the first film layer 400, the mask plate is aligned with the panel to be processed by identifying the first alignment mark 12, so that an exposure position of the first film layer 400 is accurately positioned. Further, when some subsequent film layers or formed holes directly or indirectly use the second alignment mark 13 as an alignment reference, an indirect alignment relationship is formed between these layers or formed holes and the first hole 9, so as to prevent relative position offset between these structures and the first hole 9.

The number, shape, position and size of the second alignment mark 13 and the first alignment mark 12 may not satisfy a specific relationship, and the above parameters of the two alignment marks may be the same or different.

Further, referring to FIG. 7 again, the display panel further includes a transistor layer 14, the transistor layer 14 is located on the side of the second underlay 7 away from the first blocking layer 6, and the transistor layer 14 includes a transistor 15. The transistor layer 14 may include various types of transistors 15, such as a low temperature poly-silicon (LTPS) transistor 15-1 and an indium gallium zinc oxide (IGZO) transistor 15-2.

The second alignment mark 13 is located between the second underlay 7 and the transistor layer 14.

In a more specific structure, the display panel further includes a third blocking layer 16, the third blocking layer 16 is located on a side of the second underlay 7 away from the first underlay 5, and the second alignment mark 13 is located on a side of the third blocking layer 16 away from the second underlay 7, so as to improve stability of the second alignment mark 13. Further, a shielding metal 17 is further included between the third blocking layer 16 and the transistor layer 14, the shielding metal 17 overlaps the channel of the transistor 15 in a direction perpendicular to a plane of the first underlay 5, and the shielding metal 17 is configured to prevent light from affecting channel carriers. The second alignment mark 13 may be arranged in the same layer as the shielding metal 17.

In the above structure, the second alignment mark 13 is formed by a metal layer closest to the substrate 4, in this way, each film layer and each formed hole in the transistor layer 14 may directly or indirectly use the second alignment mark 13 as an alignment reference in the manufacturing process thereof, so that each film layer and each formed hole in the transistor layer 14 may form an indirect alignment relationship with the first hole 9, thereby forming a precise alignment with the first hole 9.

In an embodiment of the present disclosure, referring again to FIG. 7, the display panel further includes the transistor layer 14, the transistor layer 14 is located on the side of the second underlay 7 away from the first blocking layer 6, and the transistor layer 14 includes the transistor 15 and a plurality of inorganic insulating layers 18.

The display panel further includes a second hole 19, the second hole 19 penetrates at least a part of the inorganic insulating layers 18, and the second hole 19 overlaps the first hole 9 in a direction perpendicular to the plane of the first underlay 5.

The display panel further includes a filling layer 20, the filling layer 20 is located at least in the second hole 19.

As described above, in the related art, when the holes are forming in the substrate, the holes are simply mechanically aligned based on the machine table, so that the holes in the substrate are easily offset from the other subsequent film layer structures in relative positions. FIG. 8 is a schematic diagram where the relative position between the first hole 9, the second hole 19, and the filling layer 20 has an offset according to an embodiment of the present disclosure. As shown in FIG. 8, when the relative position between the first hole 9, the second hole 19, and the filling layer 20 has an offset, a V-shaped large step 00 is formed between one side of the filling layer 20 and a hole wall. When a planarization layer 21 is subsequently formed, it is difficult for the planarization layer 21 to completely fill the V-shaped large step 00, thereby causing short circuit or open circuit when the trace above the planarization layer 21 crosses the V-shaped large step 00.

The trace above the planarization layer 21 may include a trace connected between the light-emitting device and the pixel circuit.

In one structure, the display panel further includes a light-emitting device layer 22 located on a side of the planarization layer 21 away from the first underlay 5. The light-emitting device layer 22 includes a light-emitting device 23. The light-emitting device 23 is located in the first area 2 and the second area 3. To further improve the transmittance of the second area 3, the pixel circuit connected to the light-emitting device 23 in the second area 3 may be arranged in the first area 2, and then the light-emitting device 23 in the second area 3 is connected to the transistor 15 of the pixel circuit in the first area 2 through a first connection line 24. The first connecting line 24 may be a single-layer trace or a multi-layer trace, for example, the first connecting line 24 includes a first sub-connecting line 24-1, a second sub-connecting line 24-2, and a third sub-connecting line 24-3 that are arranged in different layers and connected in sequence. Moreover, the first connecting line 24 may be a light-transmitting conductive trace or an opaque metal trace.

When at least part of the first connection line 24 enters the first area 2 from the second area 3, the first connection line 24 will cross the V-shaped large step 00, and the first connection line 24 is recessed in the V-shaped large step 00, which easily cause short circuit or open circuit. However, if the first connecting line 24 is short-circuited or open-circuited, it will cause poor light emission of the light-emitting device 23 in the second area 3, thereby affecting the display uniformity.

The first connection line 24 and the transistor 15 may be connected through at least one connection line. Exemplarily, the planarization layer 21 includes a first planarization layer 25 and a second planarization layer 26, and the second planarization layer 26 is located on a side of the first planarization layer 25 away from the first underlay 5. A second connection line 27 and a third connection line 28 are further connected between the first connection line 24 and the transistor 15, the second connection line 27 is located between the first planarization layer 25 and the second planarization layer 26, and the third connection line 28 is located on a side of the second planarization layer 26 away from the first planarization layer 25.

However, the embodiments of the present disclosure may effectively overcome the problem that the relative position between the first hole 9, the second hole 19, and the filling layer 20 has an offset.

The technical solutions in the embodiments of the present disclosure will be described below by taking the first mark 8 including the first alignment mark 12 as an example.

After each film layer in the transistor layer 14 is formed, the second hole 19 is first formed, then the second film layer is formed, and the second film layer is patterned to form the filling layer 20.

In one case, during the manufacturing process of the second hole 19 and the filling layer 20, the first alignment mark 12 may be directly used as an alignment reference. That is, after each film layer in the transistor layer 14 is formed, the first alignment mark 12 is identified, the mask plate is aligned with the panel to be processed, the hole drilling position of the second hole 19 is accurately positioned, and then an indirect correspondence is established between the second hole 19 and the first hole 9. In the subsequent process of patterning the second film layer, the mask plate is aligned with the panel to be processed by identifying the first alignment mark 12, and the etching position of the second film layer is accurately positioned, thereby establishing an indirect correspondence between the filling layer 20 and the first hole 9.

In this case, the first hole 9, the second hole 19 and the filling layer 20 are accurately aligned, the filling layer 20 may be better filled in the hole, and the V-shaped large step 00 will not be formed between the side wall of the filling layer 20 and the side wall of the second hole 19, so that the risk of short circuit or open circuit of the trace is avoided.

In another case, during the manufacturing process of the second hole 19 and the filling layer 20, the second alignment mark 13 may be directly used as an alignment reference. That is, after each film layer in the transistor layer 14 is formed, the second alignment mark 13 is identified, the mask plate is aligned with the panel to be processed, and the hole drilling position of the second hole 19 is accurately positioned. Since there is an alignment relationship between the second alignment mark 13 and the first hole 9, an indirect correspondence will also be established between the second hole 19 and the first hole 9. In the subsequent process of patterning the second film layer, the mask plate is aligned with the panel to be processed by identifying the second alignment mark 13, and the etching position of the second film layer is accurately positioned, thereby establishing an indirect correspondence between the filling layer 20 and the first hole 9.

In this case, the first hole 9, the second hole 19 and the filling layer 20 are accurately aligned, the filling layer 20 may be better filled in the hole, and the V-shaped large step 00 will not be formed between the side wall of the filling layer 20 and the side wall of the second hole 19, so that the risk of short circuit or open circuit of the trace is avoided.

In another case, during the manufacturing process of the second hole 19 and the filling layer 20, the second alignment mark 13 may be indirectly used as an alignment reference. That is, the transistor layer 14 further includes a third alignment mark, and the third alignment mark is formed by using the second alignment mark 13 as an alignment reference. After each film layer in the transistor layer 14 is formed, the third alignment mark is identified, the mask plate is aligned with the panel to be processed, the hole drilling position of the second hole 19 is accurately positioned, and since there is an alignment relationship between the second alignment mark 13 and the first hole 9, and there is an alignment relationship between the third alignment mark and the second alignment mark 13, an indirect correspondence relationship is also established between the second hole 19 and the first hole 9. In the subsequent process of patterning the second film layer, the mask plate is aligned with the panel to be processed by identifying the third alignment mark, and the etching position of the second film layer is accurately positioned, thereby establishing an indirect correspondence between the filling layer 20 and the first hole 9.

In this case, the first hole 9, the second hole 19 and the filling layer 20 are accurately aligned, the filling layer 20 may be better filled in the hole, and the V-shaped large step 00 will not be formed between the side wall of the filling layer 20 and the side wall of the second hole 19, so that the risk of short circuit or open circuit of the trace is avoided.

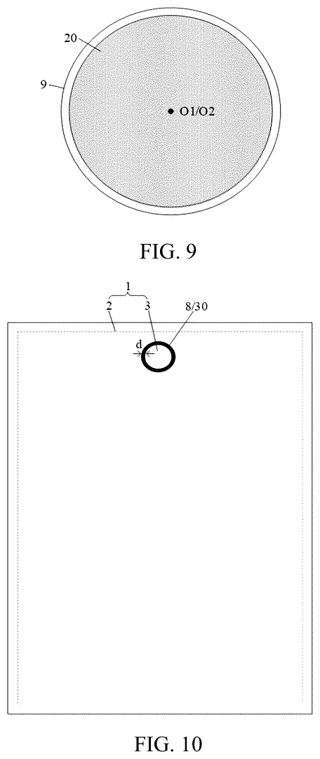

Further, FIG. 9 is a top view of a first hole and a filling layer according to an embodiment of the present disclosure. As shown in FIG. 9, a distance between a center point O1 of an orthographic projection of the filling layer 20 on the plane of the first underlay 5 and a center point O2 of an orthographic projection of the first hole 9 on the plane of the first underlay 5 is less than or equal to 2 μm, and FIG. 9 is an example in which the center point O1 and the center point O2 coincide.

Referring again to FIG. 7, there is a V-shaped groove 29 between a side wall of the filling layer 20 and a side wall of the second hole 19, and the depth of the V-shaped groove 29 is less than or equal to 1.5 μm.

With reference to the foregoing analysis, in an embodiment of the present disclosure, accurate alignment between the first hole 9 and the filling layer 20 may be achieved, so that a center point of an orthographic projection of the first hole 9 and a center point of an orthographic projection of the filling layer 20 may be substantially aligned, with no excessive offset in distance, which enables the filling layer 20 to better fill the hole completely. In some structures, referring to FIG. 6, there is no gap between the side wall of the filling layer 20 and the side wall of the second hole 19, and the filling layer 20 is well filled in the hole. In an embodiment of the present disclosure, referring to FIG. 7, even if there is a gap between the side wall of the filling layer 20 and the side wall of the second hole 19, the gap forms a V-shaped groove, the depth of the V-shaped groove will be very small and will not exceed 1.5 μm. When forming the planarization layer 21 subsequently, the planarization layer 21 will directly fill the groove completely, which avoids the trace above the planarization layer 21 from being recessed when crossing the groove and thus resulting in short circuit or open circuit.

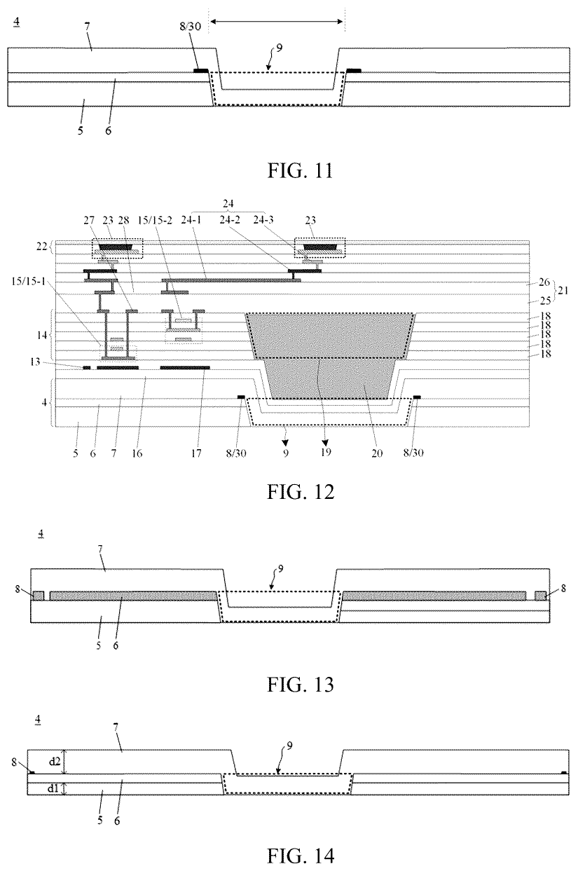

FIG. 10 is a structural schematic diagram of a display panel according to another embodiment of the present disclosure, FIG. 11 is a structural schematic diagram of a substrate according to another embodiment of the present disclosure, and FIG. 12 is a structural schematic diagram of a substrate according to another embodiment of the present disclosure. In an embodiment of the present disclosure, as shown in FIG. 10 to FIG. 12, the first mark 8 includes a first limiting mark 30, the first limiting mark 30 at least partially surrounds the first hole 9, and at least part of the edge of the first limiting mark 30 is in contact with the edge of the first hole 9. Exemplarily, the first limiting mark 30 is a closed pattern surrounding the first hole 9, for example, the first hole 9 is a circular hole, and the first limiting structure is an annular structure.

The first limiting mark 30 may be used as a clear boundary reference for the hole drilling position of the first hole 9, so as to ensure that the position and size of the first hole 9 during etching meet the requirements. Moreover, the first limiting mark 30 may also be used for subsequent visual or photographic detection of whether the actual position of the first hole 9 offsets, so as to control the alignment accuracy of the first hole 9 and other subsequent film layer structures. In addition, when the camera module is assembled below the display panel subsequently, the first limiting mark 30 may also be used as a reference alignment mark to ensure that a center of the camera coincides with a center of the first hole 9 and reduce the influence of the optical offset on the photographing quality.

Further, referring to FIG. 10 again, the width d of the first limiting mark 30 is greater than or equal to 5 μm and less than or equal to 10 μm.

The first limiting mark 30 has the width and can be directly recognized by human eyes, and after the first hole 9 is formed, it is directly and visually inspected whether the actual position of the first hole 9 offsets without photographing inspection by using an optical device such as a CCD camera.

In an embodiment of the present disclosure, the first mark 8 includes a conductive oxide material, such as indium tin oxide (ITO), or the first mark 8 includes a metal material, such as Mo.

The pattern of the first mark 8 is small, and when the first mark 8 is formed by etching, the pattern in a large area needs to be removed. Compared with dry etching, wet etching is more suitable for etching a film layer with such a large area, and both the conductive oxide material and the metal material may well meet the conditions of wet etching. Therefore, by selecting the conductive oxide material or the metal material for the first mark 8, the patterning thereof can be facilitated.

FIG. 13 is a schematic diagram of a display panel according to another embodiment of the present disclosure. In an embodiment of the present disclosure, as shown in FIG. 13, the first mark 8 and the first blocking layer 6 include the same material and are both in contact with the first underlay 5, and there is a gap between the first mark 8 and the first blocking layer 6.

In this structure, the first mark 8 and the first blocking layer 6 are formed by a same patterning process. The pattern of the film layer where the first mark 8 and the first blocking layer 6 are located is large, only the pattern in a small area needs to be removed, and the selection limit of the etching process is small, for example, patterning can be well achieved by dry etching and wet etching.

In an embodiment of the present disclosure, in order to enable the first mark 8 to be accurately identified without affecting the flatness of the upper film layer, a thickness of the first mark 8 may be set to be greater than or equal to 500 Å and less than or equal to 1000 Å in a direction perpendicular to the plane of the first underlay 5.

FIG. 14 is a schematic diagram of a display panel according to another embodiment of the present disclosure. In an embodiment of the present disclosure, as shown in FIG. 14, a thickness of the second underlay 7 is greater than a thickness of the first underlay 5, for example, the thickness of the first underlay 5 is 5 μm, and the thickness of the second underlay 7 is 10.5 μm.

When the first underlay 5 is thinner and the second underlay 7 is thicker, the second underlay 7 may fill the first hole 9 to a greater extent to reduce the recess depth of the entire substrate 4 at the first hole 9, in this way, even if a relationship of the relative positions between the first hole 9, the second hole 19 and the filling layer 20 has a offset, the influence caused by the slight offset may also be ignored.

In an embodiment of the present disclosure, a transmittance of the second underlay 7 is greater than a transmittance of the first underlay 5. The second underlay 7 is located above the first mark 8, and the transmittance of the second underlay 7 is smaller, which may reduce the shielding of the first alignment mark 12 and facilitate the identification of the first alignment mark 12.

Based on the same inventive concept, an embodiment of the present disclosure further provides a method for manufacturing a display panel, which is used for manufacturing the above display panel.

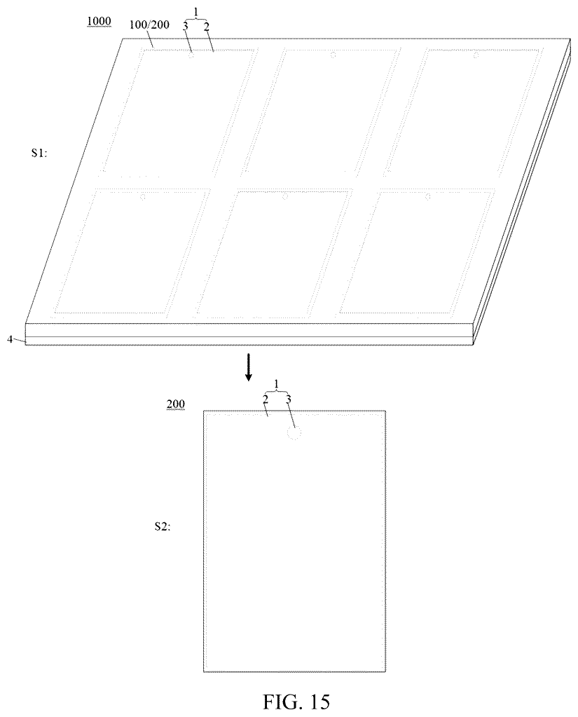

Referring to FIG. 1 and FIG. 2, FIG. 15 is a schematic diagram of a method for manufacturing a display panel according to an embodiment of the present disclosure. As shown in FIG. 15, the method includes following steps.
Step S1: a display motherboard 1000 including the substrate 4 is formed. The display motherboard 1000 includes a plurality of panel areas 100, one panel area 100 corresponds to one display panel 200. The panel area 100 includes a display area 1, the display area 1 includes a first area 2 and a second area 3, a transmittance of the second area 3 is greater than a transmittance of the first area 2.
Step S2: the display motherboard 1000 is cut to form the display panel 200.

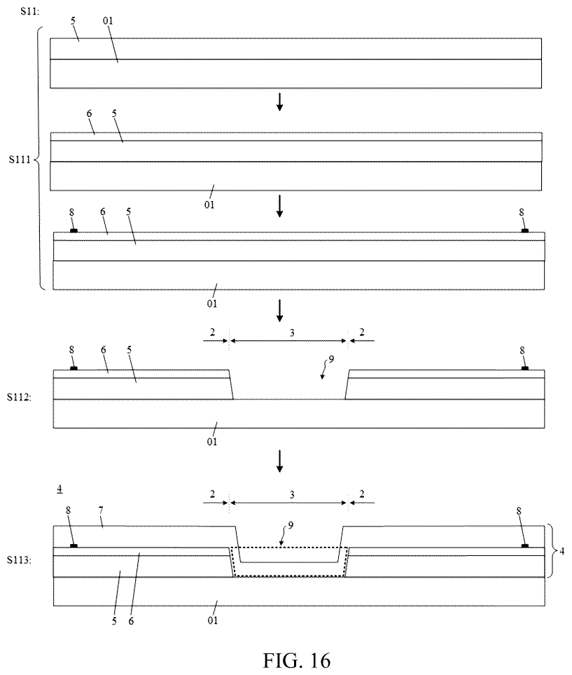

Step S1 includes step S11, and step S11 is a process of forming the substrate 4. FIG. 16 is a schematic diagram of a method for manufacturing a display panel according to another embodiment of the present disclosure. As shown in FIG. 16, the process of step S11 includes the following step.
Step S111: the first underlay 5 is formed, and the first blocking layer 6 and the first mark 8 are formed on a side of the first underlay 5.

It should be noted that, in an embodiment of the present disclosure, the first underlay 5 is formed on the carrier substrate 01, and the carrier substrate 01 may be, for example, a glass substrate. After the display motherboard 1000 is cut to form the display panel 200, the carrier substrate 01 may be peeled off.
Step S112: the first hole 9 is formed in the second area 3 and penetrates the first underlay 5 and the first blocking layer 6.
Step S113: a second underlay 7 is formed.

According to an embodiment of the present disclosure, the first mark 8 is additionally arranged in the substrate 4, and the first mark 8 may be used as an auxiliary structure for improving a hole drilling precision of the first hole 9. In the hole drilling process, the first mark 8 is identified, the hole drilling position can be positioned and limited by using the first mark 8, so that the hole drilling position is accurately controlled, and the relative position offset between the first hole 9 and other subsequent film layer structures is avoided.

Moreover, the first mark 8 may also be used to establish an indirect alignment relationship between the first hole 9 and other subsequent film layer structures. For example, in the manufacturing process, other subsequent film layer structures may directly use the first mark 8 as an alignment reference, so that an indirect alignment relationship is established between these film layer structures and the first hole 9, and the accurate alignment between these structures is achieved. In an embodiment of the present disclosure, an alignment mark A is included above the substrate 4, and the alignment mark A takes the first mark 8 as an alignment reference during the forming process to form an indirect alignment relationship between the alignment mark A and the first hole 9. Further, when some other subsequent film layer structures are formed with the alignment mark A as an alignment reference, an indirect alignment relationship may also be established between these film layer structures and the first hole to achieve accurate alignment between these structures. Further, the alignment relationship may also be transmitted upward step by step, for example, an alignment mark B may be further formed by using the alignment mark A as an alignment reference subsequently, and then an indirect alignment relationship is also formed between the alignment mark B and the first hole 9, so that when some other subsequent film layer structures use the alignment mark B as an alignment reference in the forming process, the indirect alignment relationship is also established between these film layer structures and the first hole, so that the relative position offset between these film layers or formed holes and the first hole is avoided.

In summary, the embodiments of the present disclosure can avoid the relative position offset between the formed hole in the substrate 4 and other subsequent film layer structures, further, some display defects caused by the position offset are avoided. For example, according to the technical solutions, the position offset between the formed hole in the substrate 4 and the filling layer filled in the hole may be avoided, the filling layer may better fill the hole, a V-shaped large step will not be generated on one side, so that short circuit or open circuit may be avoided when the upper trace crosses the V-shaped large step.

In an embodiment of the present disclosure, with reference to FIG. 2 and FIG. 16, in step S111, the first blocking layer 6 is formed first, and then the first mark 8 is formed, the first mark 8 is located between the first blocking layer 6 and the second underlay 7.

Forming the first mark 8 above the first blocking layer 6 may enhance the adhesion of the first mark 8, and the first mark 8 has high stability. Further, it can play a reliable role in the hole drilling of the first hole 9 and the subsequent transmission of alignment relationship.

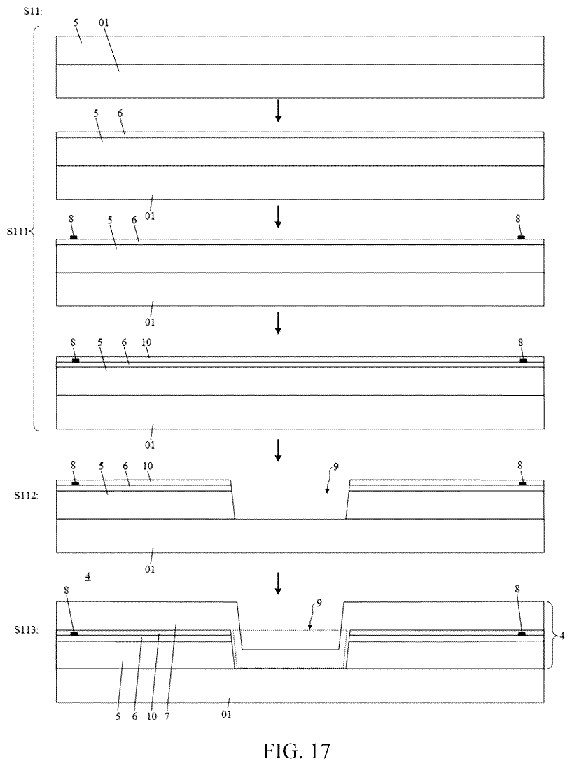

With reference to FIG. 3, FIG. 17 is a schematic diagram of a method for manufacturing a display panel according to another embodiment of the present disclosure. In an embodiment of the present disclosure, as shown in FIG. 17, in step S111, after forming the first mark 8 and before forming the second underlay 7, the manufacturing process of the substrate 4 further includes: forming the second blocking layer 10.

The blocking layer is mainly used to improve adhesion of the underlay. When the first mark 8 is formed above the first blocking layer 6, the manufacturing process of the first mark 8 may affect the first blocking layer 6, thereby affecting the adhesion of the second underlay 7. According to an embodiment of the present disclosure, the second blocking layer 10 is formed above the first mark 8, the second blocking layer 10 is not affected by the manufacturing process of the first mark 8, and the second blocking layer 10 may be firmly bonded to the second underlay 7 above.

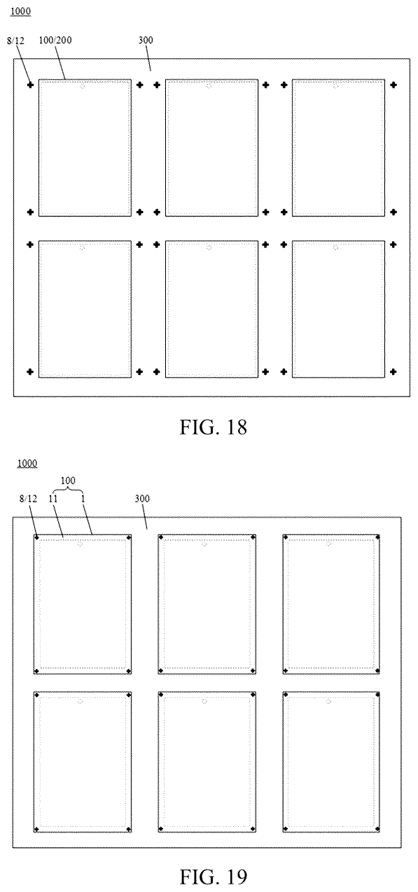

FIG. 18 is a schematic diagram of a position of a first mark according to an embodiment of the present disclosure, FIG. 19 is a schematic diagram of a position of a first mark according to another embodiment of the present disclosure. In an embodiment of the present disclosure, as shown in FIG. 19, the manufacturing process of the first mark 8 includes: forming the first alignment mark 12 at a position outside the display area 1.

The manufacturing process of the first hole 9 includes: patterning the first underlay 5 and the first blocking layer 6 with the first alignment mark 12 as an alignment reference to form the first hole 9.

The first alignment mark 12 is used for accurately positioning the hole drilling position of the first hole 9 in the manufacturing process of the first hole 9 and establishing an indirect alignment relationship between the first hole 9 and other subsequent film layer structures. Moreover, the first alignment mark 12 is arranged in the area outside the display area 1, and the size, shape, thickness and other parameters of the first alignment mark 12 may be designed more flexibly, so that the first alignment mark 12 has a larger thickness or a larger size, thereby making it easier to be identified.

In an embodiment of the present disclosure, referring to FIG. 18 again, the display motherboard further includes a non-panel area 300, the non-panel region 300 is included between adjacent panel areas 100, and the first alignment mark 12 is formed in the non-panel area 300.

In this structure, since the non-panel area 300 is cut off along with the cutting of the display motherboard 1000, the first alignment mark 12 will not remain in the display panel 200.

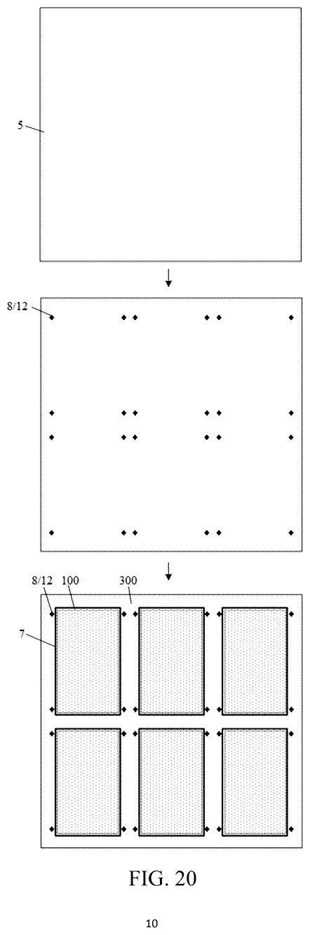

FIG. 20 is a schematic diagram of a coverage area of a second underlay according to an embodiment of the present disclosure. With reference to FIG. 18 and FIG. 20, when forming the second underlay 7, the second underlay 7 covers the panel area 100, and the second underlay 7 does not overlap the first alignment mark 12 in a direction perpendicular to the plane of the first underlay 5.

When the first alignment mark 12 is formed in the non-panel area 300, in the manufacturing method, the first alignment mark 12 is arranged outside the coating area of the second underlay 7, in this way, the second underlay 7 does not cover the first alignment mark 12, the first alignment mark 12 is exposed, and when the first alignment mark 12 is used as an alignment reference in the manufacturing process of subsequent other film layer structures, the first alignment mark 12 may be accurately identified, which helps to further improve the alignment precision between the first hole 9 and the subsequent other film layers.

In an embodiment of the present disclosure, the coverage area of the second underlay 7 may extend out of the panel area 100, that is, there is a gap between an edge of the coverage area of the second underlay 7 and an edge of the panel area 100. In this way, when cutting the display motherboard 1000, it may be ensured that the side surfaces of the first underlay 5 and the second underlay 7 in the display panel 200 are flush.

With reference to FIG. 4 and FIG. 5, in an embodiment of the present disclosure, referring to FIG. 19 again, the panel area 100 includes the non-display area 11, the non-display area 11 at least partially surrounds the display area 1, and the first alignment mark 12 is formed in the non-display area 11. For example, the first alignment mark 12 may be located at an edge of the non-display area 11 adjacent to the display panel 200, for example, at a top corner of the display panel 200 as shown in FIG. 5.

In this structure, when the display motherboard 1000 is cut, the first alignment mark 12 will remain in the display panel 200, so that it may also play a role in subsequent sample detection of the display panel 200.

With reference to FIG. 7, FIG. 21 is a schematic diagram of a method for manufacturing a display panel according to another embodiment of the present disclosure, and FIG. 22 is a schematic diagram of a method for manufacturing a display panel according to another embodiment of the present disclosure. In an embodiment of the present disclosure, as shown in FIG. 21 and FIG. 22, after the second underlay 7 is formed, the manufacturing process of the display motherboard 1000 further includes:
step S12: forming the first film layer 400, and patterning the first film layer 400 with the first alignment mark 12 as an alignment reference to form the second alignment mark 13.

In a process of exposing the first film layer 400, the mask plate is aligned with the panel to be processed by identifying the first alignment mark 12, and then the exposure position of the first film layer 400 is accurately positioned. Further, when some subsequent film layers or formed holes directly or indirectly use the second alignment mark 13 as an alignment reference, an indirect alignment relationship is formed between these layers or formed holes and the first hole 9, so as to prevent relative position offset between these structures and the first hole 9.

Further, referring to FIG. 21 and FIG. 22 again, after forming the second alignment mark 13, the manufacturing process of the display motherboard 1000 further includes following steps.
Step S13: the transistor layer 14 including a plurality of inorganic insulating layers 18 is formed.
Step S14: the transistor layer 14 is patterned by using the second alignment mark 13 as an alignment reference to form the second hole 19 penetrating at least a part of the inorganic insulating layers 18, the second hole 19 overlaps the first hole 9 in a direction perpendicular to the plane of the first underlay 5.
Step S15: the second film layer 500 is formed, and the second film layer 500 is patterned by using the second alignment mark 13 as an alignment reference to form the filling layer 20, the filling layer 20 is at least located in the second hole 19.

In the above step S14, the expression “the transistor layer 14 is patterned by using the second alignment mark 13 as the alignment reference to form the second hole 19” includes “directly or indirectly using the second alignment mark 13 as the alignment reference”. Similarly, in the above step S15, the expression “the second film layer 500 is patterned by using the second alignment mark 13 as the alignment reference to form the filling layer 20” includes “directly or indirectly using the second alignment mark 13 as the alignment reference”.

The following is specific schematic description.

In one case, during the manufacturing process of the second hole 19 and the filling layer 20, the second alignment mark 13 may be directly used as an alignment reference. That is, after each film layer in the transistor layer 14 is formed, the second alignment mark 13 is identified, the mask plate is aligned with the panel to be processed, and the hole drilling position of the second hole 19 is accurately positioned. Since there is an alignment relationship between the second alignment mark 13 and the first hole 9, an indirect correspondence will also be established between the second hole 19 and the first hole 9. In the subsequent process of patterning the second film layer, the mask plate is aligned with the panel to be processed by identifying the second alignment mark 13, and the etching position of the second film layer is accurately positioned, thereby establishing an indirect correspondence between the filling layer 20 and the first hole 9.

In this case, the first hole 9, the second hole 19 and the filling layer 20 are accurately aligned, the filling layer 20 may be better filled in the hole, and the V-shaped large step 00 will not be formed between the side wall of the filling layer 20 and the side wall of the second hole 19, so that the risk of short circuit or open circuit of the trace is avoided.

In another case, during the manufacturing process of the second hole 19 and the filling layer 20, the second alignment mark 13 may be indirectly used as an alignment reference. That is, the transistor layer 14 further includes a third alignment mark, and the third alignment mark is formed by using the second alignment mark 13 as an alignment reference. After each film layer in the transistor layer 14 is formed, the third alignment mark is identified, the mask plate is aligned with the panel to be processed, the hole drilling position of the second hole 19 is accurately positioned, and since there is an alignment relationship between the second alignment mark 13 and the first hole 9, and there is an alignment relationship between the third alignment mark and the second alignment mark 13, an indirect correspondence relationship is also established between the second hole 19 and the first hole 9. In the subsequent process of patterning the second film layer, the mask plate is aligned with the panel to be processed by identifying the third alignment mark, and the etching position of the second film layer is accurately positioned, thereby establishing an indirect correspondence between the filling layer 20 and the first hole 9.

In this case, the first hole 9, the second hole 19 and the filling layer 20 are accurately aligned, the filling layer 20 may be better filled in the hole, and the V-shaped large step 00 will not be formed between the side wall of the filling layer 20 and the side wall of the second hole 19, so that the risk of short circuit or open circuit of the trace is avoided.

In addition, after the entire layer is coated with the organic material to form the second film layer 500, the organic material at the position outside the second area 3 is removed by patterning, and only the organic material in the second area 3 is retained as the filling layer 20, so that the organic material at the position outside the second area 3 may be prevented from raising this area to form a larger step between this area and the second area 3, thereby preventing influence on subsequent planarization.

In an embodiment of the present disclosure, after the second underlay 7 is formed, the manufacturing process of the display motherboard 1000 further includes following steps.
Step S13′: the transistor layer 14 including a plurality of inorganic insulating layers 18 is formed.
Step S14′: the transistor layer 14 is patterned by using the first alignment mark 12 as an alignment reference to form the second hole 19 penetrating at least a part of the inorganic insulating layers 18, the second hole 19 overlaps the first hole 9 in a direction perpendicular to a plane of the display panel 200.
Step S15′: the second film layer 500 is formed, and the second film layer 500 is patterned by using the first alignment mark 12 as an alignment reference to form the filling layer 20, the filling layer 20 is located in the second hole 19.

The expression “using the first alignment mark 12 as an alignment reference” in Step S14′ and step S15′ may be understood as directly using the first alignment mark 12 as an alignment reference.

In the manufacturing process of the second hole 19 and the filling layer 20, the first alignment mark 12 may be directly used as an alignment reference. That is, after each film layer in the transistor layer 14 is formed, the first alignment mark 12 is identified, the mask plate is aligned with the panel to be processed, the hole drilling position of the second hole 19 is accurately positioned, and then an indirect correspondence is established between the second hole 19 and the first hole 9. In the subsequent process of patterning the second film layer, the mask plate is aligned with the panel to be processed by identifying the first alignment mark 12, and the etching position of the second film layer is accurately positioned, thereby establishing an indirect correspondence between the filling layer 20 and the first hole 9.

In this case, the first hole 9, the second hole 19 and the filling layer 20 are accurately aligned, the filling layer 20 may be better filled in the hole, and the V-shaped large step 00 will not be formed between the side wall of the filling layer 20 and the side wall of the second hole 19, so that the risk of short circuit or open circuit of the trace is avoided.

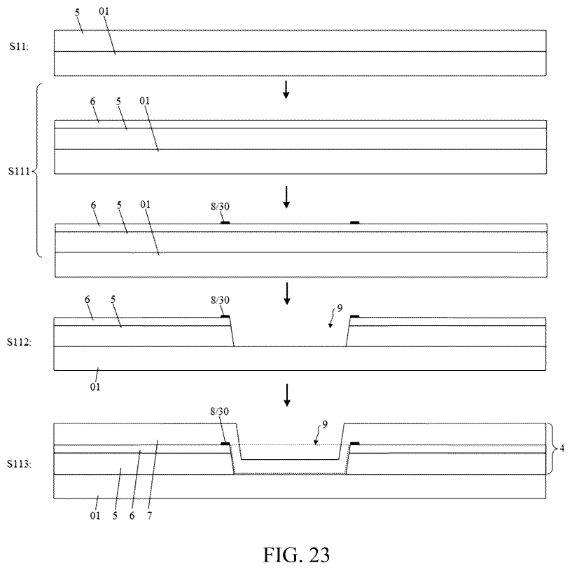

With reference to FIG. 10 and FIG. 11, FIG. 23 is a schematic diagram of a method for manufacturing a display panel according to another embodiment of the present disclosure. In an embodiment of the present disclosure, as shown in FIG. 23, the process of forming the first mark 8 includes: forming a first limiting mark 30, the first limiting mark 30 at least partially surrounds the second area 3, and an edge of the first limiting mark 30 is in contact with an edge of the second area 3.

After forming the first hole 9, at least part of the edge of the first limiting mark 30 is in contact with the edge of the first hole 9.

In the manufacturing process of the first hole 9, the first limiting mark 30 may be used to provide a clear boundary reference to ensure that the position and size of the first hole 9 during etching meet the requirements, and the first limiting mark 30 may also be used for subsequent visual or photographic detection of whether the actual position of the first hole 9 offsets, so as to control the alignment accuracy of the first hole 9 and other subsequent film layer structures. In addition, when the camera module is assembled below the display panel 200 subsequently, the first limiting mark 30 may also be used as a reference mark for mechanical alignment to ensure that the center of the camera coincides with the center of the first hole 9, thereby reducing the influence of optical offset on the photographing quality.

In an embodiment of the present disclosure, the first mark 8 is formed by a wet etching process.

The pattern of the first mark 8 is small, and when the first mark 8 is formed by etching, the pattern in the large area needs to be removed, and compared with dry etching, wet etching is more suitable for etching such a film layer with such a large area.

In an embodiment of the present disclosure, the first mark 8 is formed by the conductive oxide material or the metal material.

The pattern of the first mark 8 is small, and when the first mark 8 is formed by etching, the pattern in a large area needs to be removed. Compared with dry etching, wet etching is more suitable for etching a film layer with such a large area, and both the conductive oxide material and the metal material may well meet the conditions of wet etching. Therefore, by selecting the conductive oxide material or the metal material for the first mark 8, the patterning thereof can be facilitated.

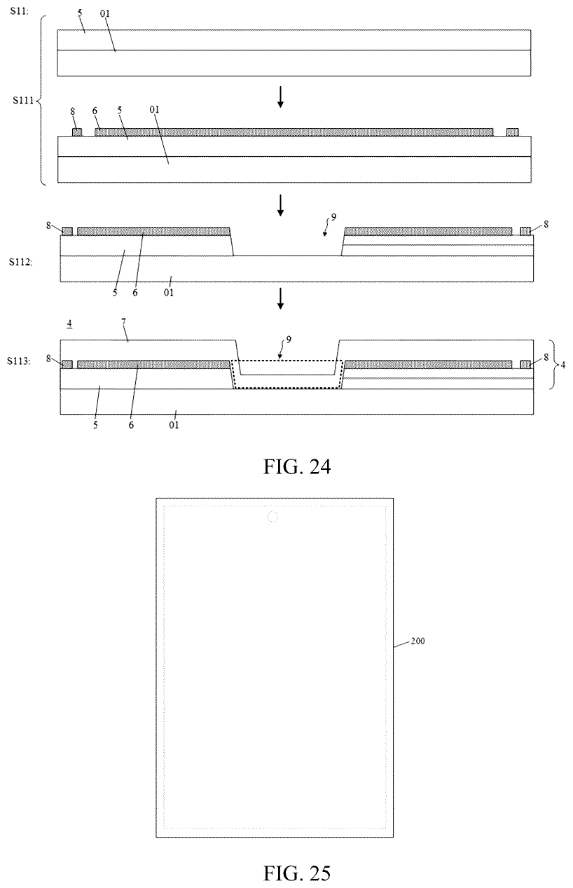

With reference to FIG. 11, FIG. 24 is a schematic diagram of a method for manufacturing a display panel according to another embodiment of the present disclosure. In an embodiment of the present disclosure, as shown in FIG. 24, the first blocking layer 6 and the first mark 8 are formed by using a same material, both the first blocking layer 6 and the first mark 8 are in contact with the first underlay 5, and there is a gap between the first blocking layer 6 and the first mark 8.

In this structure, the first mark 8 and the first blocking layer 6 are formed by a same patterning process. The pattern of the film layer where the first mark 8 and the first blocking layer 6 are located is large, only the pattern in a small area needs to be removed, and the selection limit of the etching process is small, for example, patterning can be well achieved by dry etching and wet etching.

Based on the same inventive concept, an embodiment of the present disclosure further provides a display device, FIG. 25 is a structural schematic diagram of a display device according to an embodiment of the present disclosure. As shown in FIG. 25, the display device includes the above display panel 200, or the display device is manufactured by the manufacturing method of the above display panel 200. It is understandable that the display device shown in FIG. 25 is merely illustrative, and the display device may be any electronic device having a display function such as a mobile phone, a tablet computer, a notebook computer, an e-book or a television.

The above are merely exemplary embodiments of the present disclosure, which, as mentioned above, are not used to limit the present disclosure. Whatever within the principles of the present disclosure, including any modification, equivalent substitution, improvement, etc., shall fall into the protection scope of the present disclosure.

Finally, it should be noted that the technical solutions of the present disclosure are illustrated by the above embodiments, but not intended to limit thereto. Although the present disclosure has been described in detail with reference to the foregoing embodiments, those skilled in the art can understand that the present disclosure is not limited to the specific embodiments described herein, and can make various modifications, readjustments, and substitutions without departing from the scope of the present disclosure.

What is claimed is:

1. A display panel, comprising:
a display area, wherein the display area comprises a first area and a second area, and a transmittance of the second area is greater than a transmittance of the first area; and
a substrate, wherein the substrate comprises a first underlay, a first blocking layer, a second underlay, a first hole and a first mark, wherein the second underlay is located on a side of the first blocking layer away from the first underlay, the first mark is located between the first underlay and the second underlay, and the first hole is located in the second area and penetrates the first underlay and the first blocking layer.

2. The display panel according to claim 1, wherein
the first mark is located between the first blocking layer and the second underlay.

3. The display panel according to claim 2, wherein
the substrate further comprises a second blocking layer, the second blocking layer is located between the first blocking layer and the second underlay, and the first mark is located between the first blocking layer and the second blocking layer.

4. The display panel according to claim 3, wherein
the first hole further penetrates the second blocking layer.

5. The display panel according to claim 3, wherein
the second blocking layer has a thickness less than the first blocking layer, and/or the second blocking layer has the thickness less than or equal to 2000 Å.

6. The display panel according to claim 1, further comprising a non-display area, wherein
the non-display area at least partially surrounds the display area, the first mark comprises a first alignment mark, and the first alignment mark is located in the non-display area.

7. The display panel according to claim 1, further comprising a second alignment mark and a transistor layer,
wherein the second alignment mark is located on a side of the second underlay away from the first blocking layer;
wherein the transistor layer is located on a side of the second underlay away from the first blocking layer, and the transistor layer comprises a transistor; and
the second alignment mark is located between the second underlay and the transistor layer.

8. The display panel according to claim 1, further comprising:
a transistor layer located on a side of the second underlay away from the first blocking layer, wherein the transistor layer comprises a plurality of inorganic insulating layers;
a second hole, wherein the second hole penetrates at least a part of the inorganic insulating layers, wherein the second hole overlaps the first hole in a direction perpendicular to a plane of the first underlay; and
a filling layer located at least in the second hole.

9. The display panel according to claim 1, wherein
the first mark comprises a first limiting mark, the first limiting mark at least partially surrounds the first hole; and
at least part of an edge of the first limiting mark is in contact with an edge of the first hole.

10. The display panel according to claim 1, wherein the first mark comprises a conductive oxide material or a metal material; or
the first mark and the first blocking layer comprise a same material and are both in contact with the first underlay, and a gap is formed between the first mark and the first blocking layer.

11. The display panel according to claim 1, wherein
the first mark has a thickness greater than or equal to 500 Å and less than or equal to 1000 Å in a direction perpendicular to a plane of the first underlay; or
a thickness of the second underlay is greater than a thickness of the first underlay.

12. A method for manufacturing a display panel, the method comprising:
forming a display motherboard that comprises a substrate, wherein the display motherboard comprises a plurality of panel areas, one of the plurality of panel areas corresponds to one display panel, one of the plurality of panel areas comprises a display area, the display area comprises a first area and a second area, a transmittance of the second area is greater than a transmittance of the first area;
cutting the display motherboard to form the display panel;
wherein a manufacturing process of the substrate comprises:
forming a first underlay, and forming a first blocking layer and a first mark on a side of the first underlay;
forming a first hole, the first hole is located in the second area and penetrates the first underlay and the first blocking layer; and
forming a second underlay.

13. The method according to claim 12, wherein
the first blocking layer is formed first, and then the first mark is formed, wherein the first mark is located between the first blocking layer and the second underlay; and
after forming the first mark and before forming the second underlay, the manufacturing process of the substrate further comprises: forming a second blocking layer.

14. The method according to claim 12, wherein
a manufacturing process of the first mark comprises: forming a first alignment mark at a position outside the display area;
a manufacturing process of the first hole comprises: the first underlay and the first blocking layer are patterned by using the first alignment mark as an alignment reference, to form the first hole;
the display motherboard further comprises a non-panel area between adjacent panel areas;
the first alignment mark is formed in the non-panel area; and
the second underlay covers the panel area when the second underlay is formed, and the second underlay does not overlap the first alignment mark in a direction perpendicular to a plane of the first underlay.

15. The method according to claim 12, wherein
the panel area comprises a non-display area at least partially surrounding the display area; and
the first alignment mark is formed in the non-display area.

16. The method according to claim 14, wherein after forming the second underlay, a manufacturing process of the display motherboard further comprises:
forming a first film layer;
patterning the first film layer by using the first alignment mark as an alignment reference, to form a second alignment mark;
forming a transistor layer comprising a plurality of inorganic insulating layers;
patterning the transistor layer using the second alignment mark as an alignment reference, to form a second hole penetrating at least a part of the inorganic insulating layers, wherein the second hole overlaps the first hole in a direction perpendicular to a plane of the first underlay; and
forming a second film layer, and patterning the second film layer using the second alignment mark as an alignment reference, to form a filling layer, wherein the filling layer is located in the second hole.

17. The method according to claim 14, wherein after forming the second underlay, a manufacturing process of the display motherboard further comprises:
forming a transistor layer comprising a plurality of inorganic insulating layers;
patterning the transistor layer using the first alignment mark as an alignment reference, to form a second hole penetrating at least a part of the inorganic insulating layers, wherein the second hole overlaps the first hole in a direction perpendicular to a plane of the first underlay; and
forming a second film layer, patterning the second film layer by using the first alignment mark as an alignment reference, to form a filling layer, wherein the filling layer is at least located in the second hole.

18. The method according to claim 12, wherein
a process of forming the first mark comprises: forming a first limiting mark, wherein the first limiting mark at least partially surrounds the second area;
after forming the first hole, at least part of an edge of the first limiting mark is in contact with an edge of the first hole.

19. The method according to claim 12, wherein
the first mark is formed by using a conductive oxide material or a metal material; or
the first blocking layer and the first mark are formed by using a same material, wherein both the first blocking layer and the first mark are in contact with the first underlay, and a gap is formed between the first blocking layer and the first mark.

20. A display device, comprising a display panel, wherein the display panel comprises
a display area, wherein the display area comprises a first area and a second area, and a transmittance of the second area is greater than a transmittance of the first area; and
a substrate, wherein the substrate comprises a first underlay, a first blocking layer, a second underlay, a first hole and a first mark, wherein the second underlay is located on a side of the first blocking layer away from the first underlay, the first mark is located between the first underlay and the second underlay, and the first hole is located in the second area and penetrates the first underlay and the first blocking layer.
